(19) United States
(12) Patent Application Publication
(10) Pub. No.: US 2015/0338441 A1
(43) Pub. Date: Nov. 26, 2015

(54) MEASURING TIP

(71) Applicant: ROSENBERGER HOCHFREQUENZTECHNIK GMBH & CO. KG, Fridolfing (DE)

(72) Inventor: Roland Neuhauser, Fridolfing (DE)

(21) Appl. No.: 14/655,979

(22) PCT Filed: Dec. 12, 2013
(86) PCT No.: PCT/EP2013/003757

§ 371 Date: Jun. 26, 2015

(30) Foreign Application Priority Data
Dec. 28, 2012 (DE) 20 2012 012 412.9

(51) Int. Cl. G01R 3/00; G01R 1/067

(52) U.S. Cl. CPC G01R 3/00; G01R 1/06711

(57) ABSTRACT

The present invention relates to a measuring tip having a base body, at least two measuring conductors that are connected to the base body, and at least two connecting conductors, a first connecting conductor being electrically conductively connected to one first measuring conductor of the measuring conductors and a second connecting conductor being electrically conductively connected to one second measuring conductor of the measuring conductors, the measuring conductors being fastened on a support element, and the support element being fastened on the base body by a detachable fastener so as to be replaceable.

### BACKGROUND OF THE INVENTION

1. Field of the Invention

The invention relates to a measuring tip as well as a system for the variable formation of such a measuring tip.

2. Description of Related Art

Measuring tips are for example used to test the functioning and electrical properties of circuit boards, for which purpose these are connected with a suitable measuring device via connection contacts.

Measuring tips of this generic type comprise for this purpose at least one base body with a supporting function, to which at least two measuring conductors, generally in the form of contact fingers projecting freely into space, are attached. The measuring conductors are electrically connected, directly or indirectly, with the connection contacts, which are also attached to the base body.

Such a measuring tip is for example known from EP 2 409 166 B1. In this case the measuring conductors are firmly connected, in coplanar alignment, with one or two insulating parts. This firm connection is generally effected in practice through adhesive bonding. The unit consisting of measuring conductors and insulating part(s) is arranged in a recess in the base body and is firmly connected with this. This firm connection is generally effected in practice through soldering or welding.

In order to test the electronic circuits of a circuit board, the measuring tip is placed on the latter in such a way that the measuring conductors make contact with the conductor traces of the circuit board at defined points.

The known measuring tips are configured to a particular measuring task in terms of the number and arrangement of the measuring conductors as well as their electrical connection with the connection contacts. Specifically, measuring tips for different measuring tasks differ in particular with respect to the number of measuring conductors, the distance between the measuring conductors (the so-called “pitch”) as well as the connection of the individual measuring conductors to either the signal-carrying connection contact or the ground connection contact. For example, measuring tips with three coplanar measuring conductors are widely used in which the outer measuring conductor is connected, via the electrically conductive base body, with the ground connection contact, and the central measuring conductor is connected with the signal-carrying connection contact. This design of a measuring tip is also referred to as “GSG””, where “G” stands for “Ground” and “S” for “Signal”. In measuring tips with two contact fingers, both possible configurations are widely used, i.e. both “GS” and “SG”.

The known structure of measuring tips of the generic type requires that a complete measuring tip is provided for each measuring task. Also, when the measuring conductors become worn the entire measuring tip needs to be replaced, because replacing only the measuring conductors is either impossible or is disproportionately time-consuming.

### SUMMARY OF THE INVENTION

Starting out from this state of the art, the invention was based on the problem of reducing the costs associated with the use of measuring tips of the generic type.

This problem is solved by a measuring tip in accordance with the specification and claims, as well as a system for the formation of such a measuring tip. Advantageous embodiments thereof are the subject matter of the claims and are explained in the following description of the invention.

The above and other objects, which will be apparent to those skilled in the art, are achieved in the present invention which is directed to a measuring tip comprising: a base body; at least two measuring conductors that are connected to the base body; and a second connecting conductor being electrically conductively conducted with a second measuring conductor; wherein the at least two measuring conductors are fastened on a support element and the support element is fastened on the base body by a detachable fastener so as to be replaceable.

The fastener may comprise a screw connection.

The measuring conductors are fixed to a circuit board.

The electrical connection between the measuring conductors and the connecting conductors in each connection path preferably comprises a spring contact tab, such that the circuit board makes contact with the base body and/or the connecting conductors by the spring contact tab.

The spring contact tabs are fixed to the base body and/or the connecting conductors and make contact with contact regions on the circuit board. The contact regions for making contact with the base body and/or the connecting conductors are arranged on a first side of the support element and the measuring conductors are arranged on a second side of the support element.

In a second aspect, the present invention is directed to a system for forming a measuring tip comprising: a base body; at least two measuring conductors that are connected to the base body; and at least two connecting conductors, a first connecting conductor being electrically conductively conducted with a first measuring conductor and a second connecting conductor being electrically conductively conducted with a second measuring conductor; wherein the at least two measuring conductors are fastened on a support element and the support element is fastened on the base body by a detachable fastener so as to be replaceable; wherein several measuring units are provided, each comprising the measuring conductors and the support element, wherein all the measuring units can be attached to the base body by a fastener.

### BRIEF DESCRIPTION OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIG. 1 shows a first perspective representation of a measuring tip in accordance with the invention;

FIG. 2 shows a second perspective representation of the measuring tip according to FIG. 1;

FIG. 3 shows a longitudinal section of the measuring tip according to FIGS. 1 and 2; and

FIG. 4 shows an exploded view of part of the measuring tip according to FIGS. 1 to 3.

### DESCRIPTION OF THE PREFERRED EMBODIMENT(S)

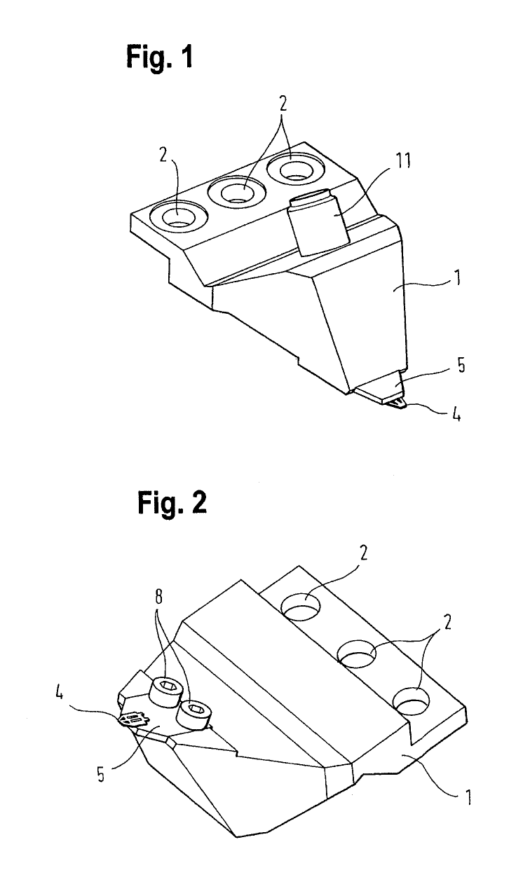

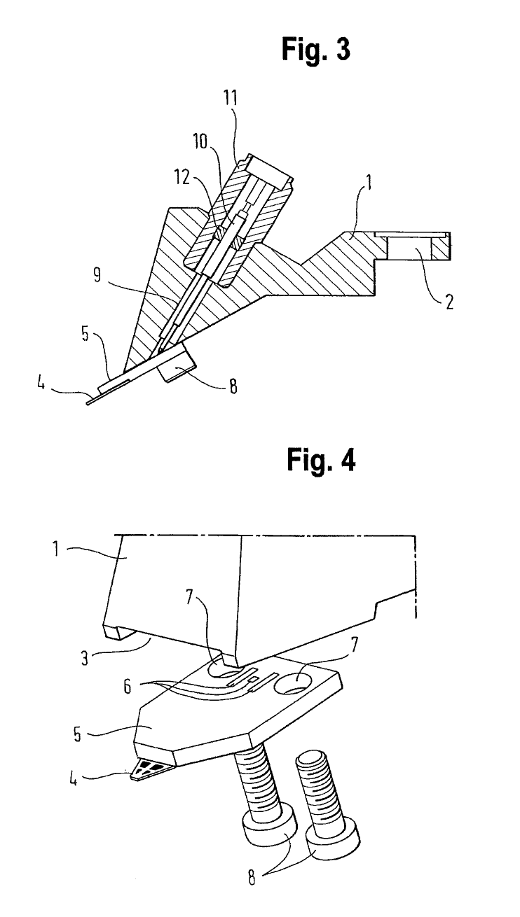

In describing the preferred embodiment of the present invention, reference will be made herein to FIGS. 1-4 of the drawings in which like numerals refer to like features of the invention.

According to the invention, a measuring tip of the generic type comprises (at least) one base body, at least two measuring conductors connected to the base body and at least two connecting conductors, a first connecting conductor being electrically conductively conducted with a first measuring conductor and a second connecting conductor being electrically conductively conducted with a second measuring conductor. According to the invention, such a measuring tip of the generic type is further developed in that the measuring conductors are fastened on a support element and the support element is fastened on the base body by a detachable fastener so as to be replaceable.

As a result of the replaceable attachment of the support element to the base body it is possible to replace the measuring unit comprising (at least) the support element and the measuring conductors attached thereto without significant expenditure of effort in order, for example, to adapt the measuring tip to a different measuring task or to replace the measuring tip with an identical measuring tip, for example if this is damaged or worn. Thus, the base body with the connection contacts can be used for the attachment of different measuring tips adapted to different measuring tasks. Nor is it necessary to replace the base body with the connection contacts simply because the measuring conductors are worn or damaged.

Fixing the measuring conductors to the base body by means of the support elements means that the fastener does not need to engage with the measuring conductors which, due to the generally very delicate dimensions of the measuring conductors, would be complicated (though possible in principle). Moreover, this can simplify the manufacture of the measuring tip, since the exact relative positioning of the measuring conductors, which is relevant for the function of the measuring tip, can advantageously take place prior to the attachment of the measuring unit to the base body.

Accordingly, a system in accordance with the invention for the formation of a measuring tip, which can be modified, inter alia, with respect to the configuration of the measuring conductors comprises several measuring units each comprising the measuring conductors and the support element, wherein all the measuring units can be attached to the (one) base body of the measuring tip by means of a fastener. The measuring units can thereby differ in the number and/or arrangement of the conductors. However, these can also be identical and in this case simply serve the purpose of replacement due to wear or damage.

The connecting conductors are preferably designed in the form of a coaxial conductor with (at least) one inner conductor and (at least) one outer conductor surrounding the inner conductor and electrically insulated from this by means of (at least) one dielectric. Such a coaxial conductor is advantageously suitable for the transmission of radio frequency signals, also in high frequency ranges. This is in particular so if, as is preferably the case, the inner conductor serves as a signal conductor and the outer conductor is the ground conductor. Particularly preferably, the coaxial conductor of the measuring tip is designed (in an end section) as a coaxial plug connector, which makes possible a simple and quick connection of the measuring tip to a measuring device, in particular by way of a coaxial cable or rigid coaxial conductor equipped with a mating plug connector.

Also preferably, it can be the case that the measuring conductors project beyond the support element and preferably also the base body and, at their points projecting freely into space, form contact points for making contact with measuring points of an electronic component which is to be tested. This allows the measuring conductors, which are preferably formed of an electrically conductive material, in particular metal(s), to be elastically deflected on making contact with the measuring points of the component which is to be tested, guaranteeing a secure contact.

In addition, it can advantageously be the case that the fastener comprises (at least) one screw connection, since both an immovable and permanent mechanical connection (with correspondingly good electrical contact) as well as simple and quick replacement can be realized by a screw connection. Naturally, however, any other fasteners, for example snap-locking connections, can also be used.

It can also preferably be the case that the measuring conductors are fixed to a circuit board. Among other things, this makes it possible for the contact between the unit consisting of support element or circuit board and measuring conductors on the one hand and the base body and/or the connection conductors on the other hand to take place via contact regions formed by the circuit board (i.e. by conductor traces on the circuit board). This allows a direct contact between the base body and/or the connecting conductors with the measuring conductors to be avoided. This is in particular advantageous because it allows, by simple means, a standardized connection interface to be achieved, also with different measuring conductor configurations.

In order to achieve reproducibly good transmission characteristics despite the replaceability of the measuring unit comprising the support element and the measuring conductors, it can also preferably be the case that the electrical connection between the measuring conductors and the connecting conductors in each connection path comprises at least one spring contact tab, i.e., a spring-mounted contact element, which makes contact with a mating contact element with a contact pressure resulting from a spring deflection. This prevents possible positioning tolerances as a result of the replaceable attachment of the measuring unit to the base body leading to poor transmission characteristics.

It can preferably be the case that the spring contact tabs are associated with the base body and/or the connecting conductors or are fixed to these. This means that the mating contact elements of the measuring unit can be designed simply, in particular as sections of conductors traces of a support element designed in the form of a circuit board.

In a further preferred embodiment of the measuring tip in accordance with the invention, the contact points which are provided for making contact with the base body and/or the coaxial conductor are arranged on a first side of the support element and the measuring conductors are arranged on a second side of the support element, preferably opposite the first side. This allows the measuring conductors with their contact points to be arranged, as far as possible, on the edge of the base body, permitting a comparatively large freedom of movement for the measuring tip, which is limited by the undesirability of contact of the base body with the electronic component which is to be tested.

The measuring tip illustrated in the drawings comprises a base body 1. This can for example be formed of brass. On a rear end, the base body 1 possesses three mounting openings 2 by means of which the measuring tip can be fixed to a structure which is not shown, for example a robotic arm. A recess 3 is formed on the front end of the base body which serves to accommodate a measuring unit.

The measuring unit comprises several, in the present exemplary embodiment coplanar, measuring conductors 4 made of metal which are arranged at defined distances from one other and which are firmly attached to an underside of a circuit board 5. The measuring conductors 4 are electrically insulated from one another. The measuring conductors 4 are fixed in place through soldering. The three measuring conductors 4 are in each case electrically connected with a contact region 6 on the upper side of the circuit board 5 via conductor traces of the circuit board 5 (not shown). The circuit board 5 also has two through-openings 7 formed in its carrier board which serve to accommodate screws 8, by means of which the measuring unit is or can be replaceably attached to the base body 1. For this purpose, the screws 8 are screwed into corresponding threaded bores in the base body 1.

The base body 1 also has a reception opening 9 which serves to receive a coaxial conductor. The coaxial conductor comprises an inner conductor 10 as well as an outer conductor 11, which is arranged at a distance from the inner conductor 10. In a section of the coaxial conductor, a support 12 made of an electrically insulating material secures the relative position of the inner conductor 10 and outer conductor 11. In the remaining sections, air serves as a dielectric. On a plug-side end, the coaxial conductor forms a (coaxial) connector. This serves to receive a coaxial mating plug connector, which can for example be arranged on the end of a coaxial cable (not shown) via which the measuring tip can be connected electrically with a measuring device, which is not shown.

The outer conductor 11 of the coaxial conductor is in direct contact with the base body 1, and is thus electrically connected with this. The inner conductor 10, which extends through the stepped reception opening as far as the recess 3, is, in the section which is no longer surrounded by the outer conductor 11, insulated from the base body 1 by means of air as a dielectric.

In the region of the recess 3 the inner conductor 10 makes direct contact with the centermost of the contact regions 6 on the circuit board 5. In contrast, the two outer contact regions 6 make direct contact with the base body 1, whereby in an alternative embodiment which is not shown it can also be the case that contact is made via spring contact tabs, which for this purpose are advantageously connected with the base body 1, in order to guarantee secure contact even in the event of deviations in the relative position of the circuit board 5 and base body 1 resulting from tolerances. The inner conductor 10 can also make contact with the central contact region 6 by means of one or more spring contact tabs, which are preferably fixed to the inner conductor 10.

The central measuring conductor 4, the central contact region 6, the conductor trace of the circuit board 5 connecting these as well as the inner conductor 10 of the coaxial conductor form part of a signal path when the measuring tip is being used to test an electronic component. In contrast, the outer measuring conductors 4, the outer contact regions 6, the conductor traces of the circuit board 5 connecting these, the base body 1 as well as the outer conductor 11 of the coaxial conductor are connected to ground. The measuring conductors of the measuring tip illustrated in the drawings are thus designed in a so-called “GSG” configuration.

The measuring conductors 4 project beyond the circuit board 5 and thus also the base body 1 and as a result project freely into space. This means that they can, individually, deflect elastically on making individual contact with defined measuring points of the component which is to be tested. This ensures a more secure contact of all measuring conductors 4 with the measuring points, even where the position of the measuring tip is slightly twisted relative to the electronic component.

The design of the measuring tip according to the innovation makes it possible to replace the measuring unit simply and quickly with an identical or different measuring unit. This can for example be practical if a different configuration of the measuring conductors 4 is necessary for a new measuring task or a measuring unit needs to be replaced due to the measuring conductors 4 being worn. The base body 1 together with the coaxial conductor can continue to be used.

The replaceability of the measuring unit is guaranteed in that the circuit boards 5 of all provided measuring units have identically arranged through-openings 7 and contact regions 6 (insofar as these are required) in order to guarantee combination with the same unit consisting of base body 1 and coaxial conductor.

While the present invention has been particularly described, in conjunction with a specific preferred embodiment, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

Thus, having described the invention, what is claimed is:

1. A measuring tip comprising:
a base body;
at least two measuring conductors that are connected to the base body; and
at least two connecting conductors, a first connecting conductor being electrically conductively conducted with a first measuring conductor and a second connecting conductor being electrically conductively conducted with a second measuring conductor;
wherein the at least two measuring conductors are fastened on a support element and the support element is fastened on the base body by a detachable fastener so as to be replaceable.

2. The measuring tip of claim 1, wherein the fastener comprises a screw connection.

3. The measuring tip of claim 1, wherein the measuring conductors are fixed to a circuit board.

4. The measuring tip of claim 1, wherein the electrical connection between the measuring conductors and the connecting conductors in each connection path comprises a spring contact tab.

5. The measuring tip of claim 4, including having the circuit board make contact with the base body and/or the connecting conductors by the spring contact tabs.

6. The measuring tip of claim 5, wherein the spring contact tabs are fixed to the base body and/or the connecting conductors and make contact with contact regions on the circuit board.

7. The measuring tip of claim 6, wherein contact regions for making contact with the base body and/or the connecting conductors are arranged on a first side of the support element and the measuring conductors are arranged on a second side of the support element.

8. A system for forming a measuring tip comprising:
a base body;
at least two measuring conductors that are connected to the base body; and
at least two connecting conductors, a first connecting conductor being electrically conductively conducted with a first measuring conductor and a second connecting conductor being electrically conductively conducted with a second measuring conductor;
wherein the at least two measuring conductors are fastened on a support element and the support element is fastened on the base body by a detachable fastener so as to be replaceable;
wherein several measuring units are provided, each comprising the measuring conductors and the support element, wherein all the measuring units can be attached to the base body by a fastener.

9. The measuring tip of claim 2, wherein the measuring conductors are fixed to a circuit board.

10. The measuring tip of claim 9, wherein the electrical connection between the measuring conductors and the connecting conductors in each connection path comprises a spring contact tab.
